(19) United States
(12) Patent Application Publication
(10) Pub. No.: US 2023/0167542 A1
(43) Pub. Date: Jun. 1, 2023

(54) FILM FORMING APPARATUS

(71) Applicant: TOKYO ELECTRON LIMITED, Tokyo (JP)

(72) Inventors: Junichi TAKEI, Yamanashi (JP); Shinji ORIMOTO, Yamanashi (JP); Shinji FURUKAWA, Tokyo (JP)

(21) Appl. No.: 17/905,989

(22) PCT Filed: Feb. 26, 2021
(86) PCT No.: PCT/JP2021/007296

§ 371 Date: Sep. 9, 2022

(30) Foreign Application Priority Data
Mar. 12, 2020 (JP) 2020-043408

(51) Int. Cl. C23C 14/50; C23C 14/35

(52) U.S. Cl. CPC C23C 14/50; C23C 14/35; H01J 37/3435

(57) ABSTRACT

A film forming apparatus for forming a film on a moving substrate by sputtering includes a processing container, a placement base having a placement surface on which a substrate is placed, a holder configured to hold a target, an upper shield member configured to divide a space in the processing container into an upper space and a lower space, a movement mechanism configured to move the placement base in a movement direction parallel to the placement surface and to move the placement base in the vertical direction, a leg member configured to connect the placement base and the movement mechanism, and a lower shield member configured to define the movement space together with the upper shield member. The lower shield member includes a fixed shield member and a moving shield member.

### TECHNICAL FIELD

The present disclosure relates to a film forming apparatus.

### BACKGROUND

A film forming apparatus disclosed in Patent Document 1 includes: a chamber body that provides a chamber; and a slit plate that is disposed to partition the chamber into a first space and a second space below the first space, and has a slit penetrating therethrough. This film forming apparatus further includes: a holder disposed to hold a target in the first space; a stage that supports the substrate and is movable in a movement direction orthogonal to a longitudinal direction of the slit in a movement area including a space directly below the slit; and a movement mechanism that moves the stage along the movement direction. In Patent Document 1, the stage has one or more protrusions that provide portions that are bent upward and/or downward in a passage around the stage between the slit and the other area in the second space other than the movement area in order to prevent particles from the target from scattering to the other area. Further, in Patent Document 1, the stage has a placement portion including a placement area on which a substrate is placed, and a support portion that supports the placement portion.

The support portion extends below the placement portion, and is coupled to the movement mechanism. The one or more protrusions include a first protrusion formed at the support portion. The film forming apparatus disclosed in Patent Document 1 further includes: a wall member that is coupled to the slit plate and defines the movement area. The wall member is disposed between the movement area and the other area in the second space. The wall member includes a portion that provides a first recess into which the first protrusion is inserted. The wall member provides, at its one end in the movement direction, an opening through which the stage passes to enter the movement area and retract from the movement area. The film forming apparatus further includes a lid for opening and closing the opening. When the stage enters the movement area or retracts from the movement area, the lid is moved upward to retract to the first space.

### PRIOR ART DOCUMENTS

### Patent Documents

Patent Document 1: Japanese Patent Application Publication No. 2018-90876

### SUMMARY

### Problems to Be Resolved by the Invention

The technique of the present disclosure enables, in a film forming apparatus for forming a film by sputtering on a moving substrate, a larger number of members to be additionally provided in a space in which a target is disposed while suppressing unnecessary deposition of sputtered particles from the target.

### Means for Solving the Problem

One aspect of the present disclosure provides a film forming apparatus for forming a film on a moving substrate by sputtering comprising a processing container configured to be depressurized, a placement base disposed in the processing container and having a placement surface on which a substrate is placed, a holder disposed in the processing container and configured to hold a target, an upper shield member configured to divide a space in the processing container into an upper space in which the holder is positioned and a lower space in which the placement base is positioned, and has a slit penetrating therethrough in a vertical direction, a movement mechanism configured to move the placement base in a movement direction parallel to the placement surface and to move the placement base in the vertical direction, in a movement space including a space directly below the slit in the lower space, a leg member configured to connect the placement base and the movement mechanism, and a lower shield member configured to define the movement space together with the upper shield member. The lower shield member includes a fixed shield member fixed in the lower space and having an opening forming an intake outlet of the placement base with respect to the movement space, and configured to define a path space, the path space configured to connect the movement space and other space in the lower space and through which the leg member passes when the placement base moves in the movement direction, and a moving shield member configured to be movable in the lower space, the moving shield member configured to be moved downward in the lower space to open the opening and moved upward in the lower space to close the opening to thereby define the movement space and the path space, wherein the path space has a serpentine shape in a cross-section taken along the movement direction, and the leg member has a shape corresponding to the path space in a cross-section taken along the movement direction.

### Effect of the Invention

In accordance with the present disclosure, in a film forming apparatus for forming a film by sputtering on a moving substrate, it is possible to additionally provide a larger number of members in a space where a target is disposed while suppressing unnecessary deposition of sputtered particles from the target.

### BRIEF DESCRIPTION OF THE DRAWINGS

FIG. 1 is a vertical cross-sectional view schematically showing an outline of a configuration of a film forming apparatus according to the present embodiment, and shows a state in which an opening of a fixed shield member is closed. FIG. 2 shows a state in which the opening is opened.

FIG. 2 is a vertical cross-sectional view schematically showing the outline of the configuration of the film forming apparatus according to the present embodiment, and shows a state in which the opening of the fixed shield member is opened.

FIG. 3 is a partially enlarged view of FIG. 1.

FIG. 4 shows a part of a cross section taken along a line A-A of FIG. 1.

FIG. 5 schematically shows a state of the film forming apparatus during film formation.

FIG. 6 schematically shows a state of the film forming apparatus during film formation.

FIG. 7 schematically shows a state of the film forming apparatus during film formation.

FIG. 8 is a top view of the fixed shield member.

FIG. 9 is a partially enlarged view of FIG. 2.

FIG. 10 is a partially enlarged cross-sectional view showing a lower shield member in an area exposed to an upper space through a slit.

FIG. 11 is a partially enlarged cross-sectional view showing the lower shield member in an area that is not exposed to the upper space through the slit.

FIG. 12 explains another example of a moving shield member.

### DETAILED DESCRIPTION

In a semiconductor device manufacturing process, a film forming process for forming a desired film such as a metal film or the like is performed on a substrate such as a semiconductor wafer (hereinafter referred to as “wafer”) or the like. Sputtering is known as the film forming process.

A film forming apparatus for performing sputtering includes, in a processing container that can be depressurized, a holder for holding a target for releasing sputtered particles and a placement base on which the substrate is placed. A shield member penetrating in a vertical direction may be disposed between the holder and the placement base. The placement base may be configured to be movable in a horizontal direction in a space below the shield member. In this case, the sputtered particles are released into the space below the shield member through the slit, and deposited on the substrate placed on the placement base moving in the horizontal direction, thereby forming a film.

In the film forming apparatus as described above, the sputtered particles from the target are unnecessarily deposited on a portion other than the substrate in the space below the shield member. Patent Document 1 discloses the film forming apparatus for suppressing such unnecessary deposition.

However, in the film forming apparatus disclosed in Patent Document 1, the wall member that defines the movement area in which the stage supporting the substrate moves during film formation has the opening at its one end in the movement direction of the stage. Further, when the stage enters the movement area, the lid for opening and closing the opening is moved upward to retract into the space where the holder for the target is disposed. In the configuration in which the lid retracts into the space where the holder for holding the target is disposed, if an additional member (e.g., another holder for holding the target, a member for adjusting a film formation type, or the like) is additionally provided in the space, the additionally provided member may interfere with the retracted lid. In other words, it may not be possible to additionally provide a member in the space.

Therefore, the technique of the present disclosure enables, in a film forming apparatus for forming a film by sputtering on a moving substrate, a larger number of members to be additionally provided in the space where the holder holding the target is disposed while suppressing unnecessary deposition of sputtered particles from the target.

Hereinafter, the configuration of the film forming apparatus according to the present embodiment will be described with reference to the accompanying drawings. In this specification, like reference numerals will be given to like parts substantially having the same functions and configurations, and redundant description thereof will be omitted. In the cross-sectional view to be referred to in the following description, the outline behind the cut surface is omitted for some members.

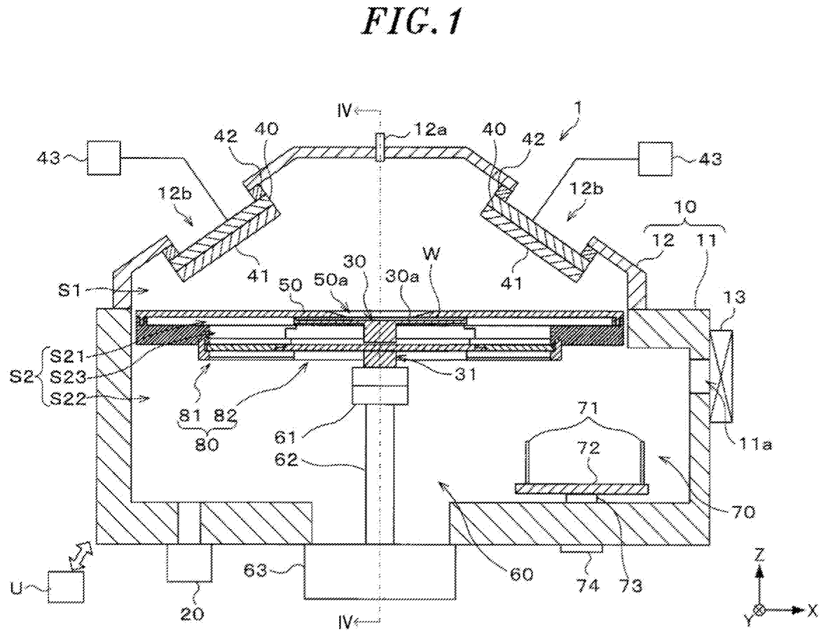

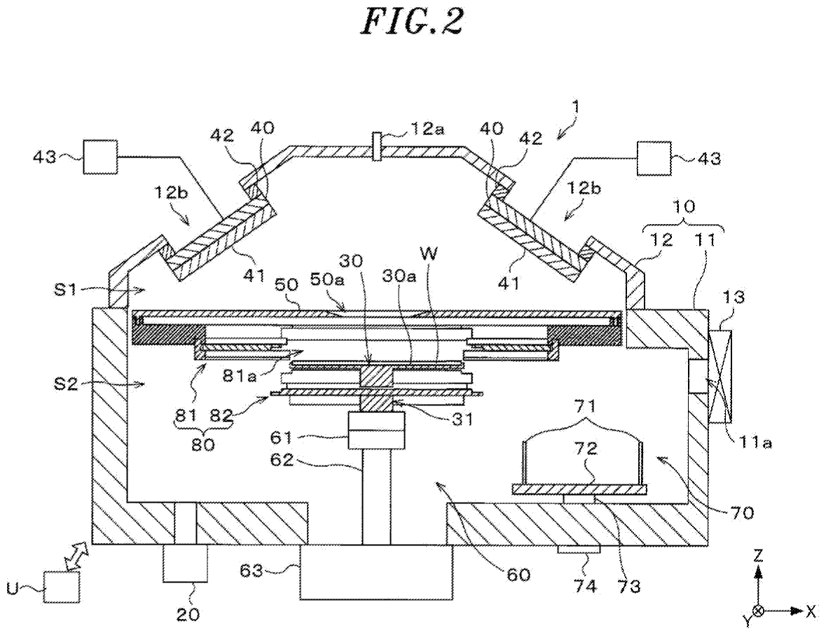

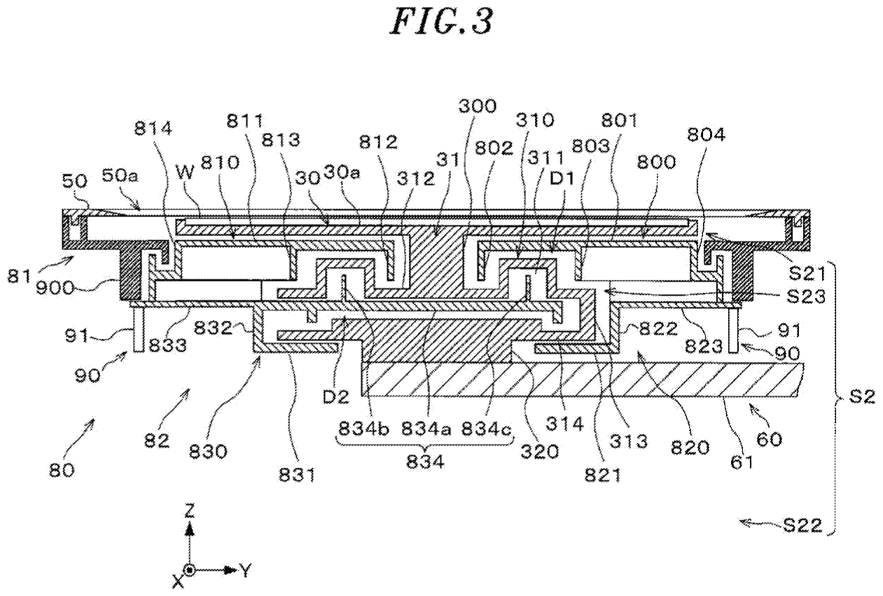

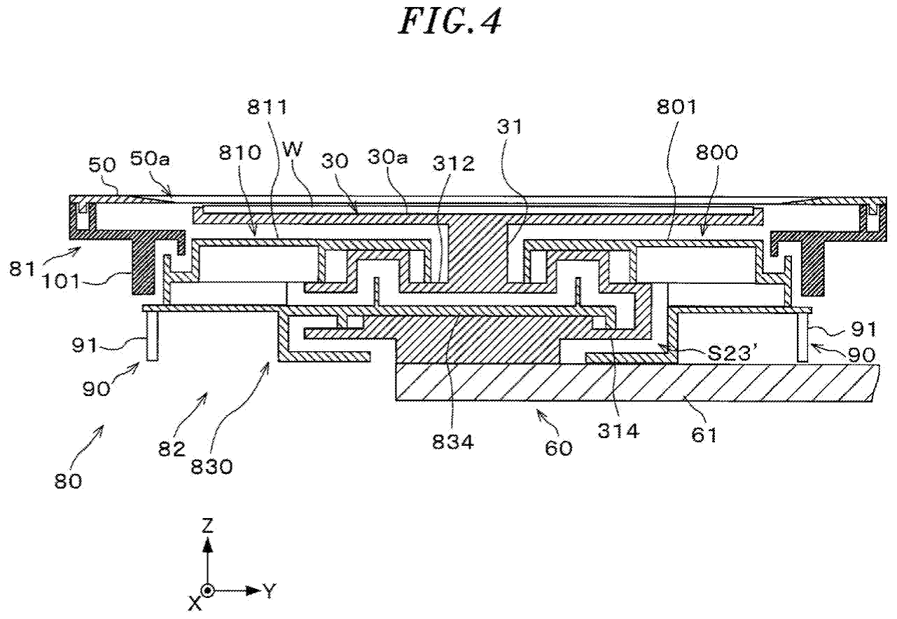

FIGS. 1 and 2 are vertical cross-sectional views schematically showing an outline of the configuration of the film forming apparatus 1 according to the present embodiment. FIG. 1 shows a state in which an opening of a fixed shield member to be described later is closed. FIG. 2 shows a state in which the opening is opened. FIG. 3 is a partially enlarged view of FIG. 1. FIG. 4 shows a part of the cross section taken along a line A-A of FIG. 1.

The film forming apparatus 1 of FIGS. 1 and 2 forms a film on a substrate by sputtering. Specifically, a metal film is formed on a wafer W as a substrate, for example. The film forming apparatus 1 includes a processing container 10.

The processing container 10 is configured to be depressurized and accommodates the wafer W. The processing container 10 has a container body 11 and a lid 12. The container body 11 and the lid 12 are made of aluminum or the like, and are electrically connected to a ground potential.

The container body 11 is formed in a hollow shape having an upper opening and a closed bottom.

An exhaust device 20 for reducing a pressure in a sealed space in the processing container 10 is connected to a bottom portion of the container body 11 through a chamber valve (not shown). A loading/unloading port lla for a wafer W is formed on a sidewall of the container body 11, and is provided with a gate valve 13 for opening and closing the loading/unloading port 11a.

The lid 12 is formed in a dome shape, and is attached to an upper portion of the container body 11 to close the upper opening of the container body 11.

Further, the lid 12 is provided with a gas introducing member 12a. The gas introducing member 12a introduces a gas from a gas supply source (not shown) into the processing container 10.

An O-ring (not shown) as a sealing member is disposed between the container body 11 and the lid 12 to seal the space therebetween.

A placement base 30 having on an upper surface thereof a placement surface 30a on which the wafer W is horizontally placed is disposed in the processing container 10. The placement base 30 may be provided with at least one of a heater for heating the wafer W placed on the placement surface 30a and a cooling mechanism.

Further, two holders 40 made of a conductive material are disposed in the space above the placement base 30 in the processing container 10. Each holder 40 holds a target 41 such that the target 41 is disposed in the processing container 10. The holder 40 is attached to the lid 12. A through-hole 12b is formed at the portion of the lid 12 to which the holder 40 is attached. An insulating member 42 is disposed on an inner wall surface of the lid 12 to surround the through-hole 12b. The holder 40 is attached to the lid 12 via the insulating member 42 to close the through-hole 12b.

The holder 40 holds the target 41 such that the target 41 is positioned diagonally above a slit 50a of the upper shield member 50 to be described later, for example. One holder 40 is positioned on a back side (negative side in the X-direction in the drawing) with respect to the slit 50a of the upper shield member 50 to be described later, and the other holder 40 is positioned on a front side (positive side in the X-direction in the drawing) with respect to the slit 50a of the upper shield member 50. The holders 40 have the same height, and the distances from the holders 40 to the slit 50a in the device depth direction (X-direction in the drawing) are the same. In other words, the holders 40 are disposed at symmetrical positions with respect to a surface (the YZ plane in the drawing) extending in the height direction and the device width direction through the slit 50a of the upper shield member 50.

Further, each holder 40 holds the corresponding target 41 such that the target 41 faces the slit 50a of the upper shield member 50, i.e., such that the target 41 faces the wafer W that is a film formation target through the slit 50a of the upper shield member 50.

The target 41 is formed in a rectangular shape in plan view. The length of the target 41 in the device width direction (Y-direction in the drawing) is greater than the diameter of the wafer W that is a film formation target.

A power supply 43 is connected to each holder 40, and a negative DC voltage is applied from the power supply 43 thereto. An AC voltage may be applied instead of the negative DC voltage.

Further, a magnet unit (not shown) is disposed on a surface of each holder 40 opposite to a surface facing the target 41.

Further, the upper shield member 50 is disposed in the processing container 10. The upper shield member 50 is a flat plate-shaped member having the slit 50a. The upper shield member 50 is disposed to divide the space in the processing container 10 into an upper space S1 where the holder 40 is disposed and a lower space S2 where the placement base 30 is disposed. The upper shield member 50 may include one component or multiple components.

The slit 50a is formed through the upper shield member 50 in a vertical direction (Z-direction in the drawing). The slit 50a has a long rectangular shape in the device width direction (Y-direction in the drawing) orthogonal to the device depth direction (X-direction in the drawing), which is the direction in which the placement base 30 is moved by a movement mechanism 60 to be described later, in plan view. The length of the slit 50a in the device depth direction (X-direction in the drawing) is smaller than the diameter of the wafer W, and the length of the slit 50a in the device width direction (Y-direction in the drawing) is greater than the diameter of the wafer W.

The movement mechanism 60 for moving the placement base 30 is disposed in the lower space S2 in the processing container 10. The movement mechanism 60 moves the placement base 30 in a movement space S21 in the movement direction parallel to the placement surface 30a of the placement base 30, i.e., in the device depth direction (X-direction in the drawing). The movement space S21 includes the space directly below the upper shield member 50 and the space directly below the slit 50a in the lower space S2.

Further, the movement mechanism 60 moves the placement base 30 in the vertical direction (Z-direction in the drawing).

As shown in FIGS. 1 and 3, the movement mechanism 60 and the placement base 30 are connected by a leg member 31. One end of the leg member 31 is connected to a center of a bottom surface of the placement base 30, and the other end of the leg member 31 is connected to a tip end of a multi-joint arm 61 (to be described later) of the movement mechanism 60. The leg member 31 will be described in detail later.

As shown in FIGS. 1 and 2, the movement mechanism 60 has, e.g., the multi-joint arm 61, a driving shaft 62, and a driving device 63.

The placement base 30 is attached to the tip end of the multi-joint arm 61. Specifically, the placement base 30 is attached via the leg member 31. The base of the multi-joint arm 61 is supported at an upper end of the driving shaft 62.

The driving device 63 is connected to a lower end of the driving shaft 62. The driving shaft 62 is positioned on the back side (negative side in the X-direction in the drawing) compared to a delivery mechanism 70 to be described later.

The driving device 63 has, e.g., a motor, to generate a driving force for rotating the driving shaft 62 and a driving force for vertically moving the driving shaft 62.

The driving device 63 linearly moves the tip end of the multi-joint arm 61 in the device depth direction (X-direction in the drawing) by rotating the driving shaft 62, thereby linearly moving the placement base 30 in the device depth direction (X-direction in the drawing). Further, the driving device 63 linearly moves the placement base 30 in the vertical direction (Z-direction in the figure) by vertically moving the driving shaft 62.

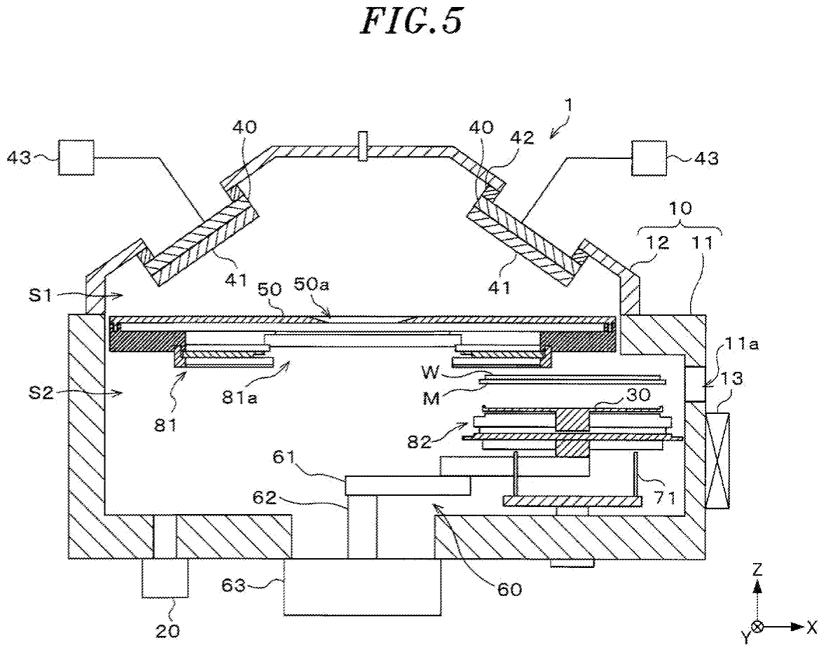

The delivery mechanism 70 is disposed on the loading/unloading port lla side in the lower space S2 in the processing container 10. The delivery mechanism 70 is used to deliver the wafer W between a transfer mechanism M (see FIG. 5) for the wafer W that enters the processing container 10 from the loading/unloading port lla and the placement base 30.

The delivery mechanism 70 has a plurality of (e.g., three) support pins 71, a support member 72, a driving shaft 73, and a driving device 74.

The support pins 71 are rod-shaped members, and are supported by the support member 72 to extend in the vertical direction.

The support member 72 is connected to an upper end of the driving shaft 73. The driving device 74 is connected to a lower end of the driving shaft 73.

The driving device 74 has, e.g., a motor, to generate a driving force for vertically moving the driving shaft 73.

The driving device 74 vertically moves the driving shaft 73 so that the support pins 71 penetrate through the placement surface 30a through through-holes (not shown) formed in a moving shield member 82 to be described later and through-holes (not shown) formed in the placement base 30.

A lower shield member 80 that defines the movement space S21 together with the upper shield member 50 is disposed in the lower space S2 in the processing container 10. For example, the upper shield member 50 defines an upper surface of the movement space S21, and the lower shield member 80 defines a side surface and a bottom surface of the movement space S21.

The lower shield member 80 defines a path space S23 as shown in FIG. 3. The path space S23 connects the movement space S21 in the lower space S2 and other spaces S22, and the leg member 31 passes through the path space S23 when the placement base 30 moves in the movement space S21 in the device depth direction (X-direction in the drawing). Further, the path space S23 extends linearly along the device depth direction (X-direction in the drawing). In the other space S22, the movement mechanism 60, the delivery mechanism 70, and a movement mechanism 90 to be described later are disposed, for example.

The lower shield member 80 has a fixed shield member 81 and the moving shield member 82.

The fixed shield member 81 is fixed in the lower space S2 and has an opening 81a forming an intake outlet of the placement base 30 with respect to the movement space S21 as shown in FIG. 2. The opening 81a is formed at a central portion of the fixed shield member 81 in the device depth direction (X-direction in the drawing), and the center thereof is positioned on the axis of the driving shaft 62 of the movement mechanism 60.

The moving shield member 82 is configured to be movable in the lower space S2, and is vertically moved to open or close the opening 81a of the fixed shield member 81. When the moving shield member 82 is moved downward to open the opening 81a as shown in FIG. 2, the placement base 30 can move into and out of the movement space S21. Further, when the moving shield member 82 is moved upward to close the opening 81a as shown in FIG. 1, the movement space S21 is defined and the path space S23 is defined.

As shown in FIG. 3, the path space S23 defined by the lower shield member 80 has a serpentine shape in a cross-section taken in the device depth direction (X-direction in the drawing). In other words, the path space S23 forms a labyrinth structure in the cross-section taken in the device depth direction (X-direction in the drawing). The path space S23 has a serpentine shape that is folded back at least once in both the vertical direction (Z-direction in the drawing) and the device width direction (Y-direction in the drawing) in the cross-section taken in the device depth direction (X-direction in the drawing), for example. The path space S23 in the example of the drawing has a serpentine shape that is folded back twice in the vertical direction (Z-direction in the drawing) and once in the device width direction (Y-direction in the drawing) in the cross-section taken in the device depth direction (X-direction in the figure).

As shown in FIG. 4, the moving shield member 82 can be supported from below by the leg member 31 in a state where the leg member 31 is located in a space S23′ forming the path space S23. Therefore, when the placement base 30 is moved by the movement mechanism 60, the moving shield member 82 supported by the leg member 31 can also be moved.

Further, the moving shield member 82 can be vertically moved independently from the leg member 31 by the movement mechanism 90 to be described later. The moving shield member 82 is no longer supported by the leg member 31 when it is moved upward independently from the leg member 31.

Further, the leg member 31 that moves in the path space S23 in the device depth direction (X-direction in the drawing) has a shape corresponding to the path space S23 in the cross-section taken in the device depth direction so that the movement in the device depth direction is not hindered by the lower shield member 80 that defines the path space S23. Specifically, the leg member 31 is bent along the shape of the path space S23 in the cross-section taken in the device depth direction (X-direction in the drawing).

Further, as shown in FIG. 3, another movement mechanism 90 is disposed in the lower space S2. The movement mechanism 90 moves the moving shield member 82 in the vertical direction independently from the placement base 30.

A plurality of movement mechanisms 90 are provided, for example. Each of the movement mechanisms 90 has one support pin 91 and a driving device (not shown), for example.

The support pin 91 is a rod-shaped member, and is connected to the driving device to extend in the vertical direction.

The driving device has, e.g., a motor, to generate a driving force for moving the support pin 91 in the horizontal plane and a driving force for vertically moving the support pin 91. The driving device may have a multi-joint arm or a guide member to move the support pin 91 in a predetermined direction in the horizontal plane.

The driving device moves the support pin 91 in the horizontal plane to move the support pin 91 to a position below a peripheral portion of the moving shield member 82 or to retract the support pin 91 from the position below the peripheral portion of the moving shield member 82. Further, the driving device vertically moves the support pin 91 to linearly move the moving shield member 82 in the vertical direction independently from the leg member 31.

The film forming apparatus 1 further includes a controller U. The controller U is, e.g., a computer having a CPU, a memory, or the like, and includes a program storage (not shown). The program storage stores a program for controlling the movement mechanism 60, the delivery mechanism 70, the movement mechanism 90, or the like to realize film formation to be described later in the film forming apparatus 1. The program may be recorded in a computer-readable storage medium, and may be installed on the controller U from the storage medium. A part or the entire program may be realized by a dedicated hardware (circuit board).

Next, film formation performed by the film forming apparatus 1 will be described with reference to FIGS. 5 to 7 in addition to FIGS. 3 and 4. FIGS. 5 to 7 schematically show a state of the film forming apparatus 1 during film formation.

First, as shown in FIG. 5, the gate valve 13 of the processing container 10 having a pressure adjusted to a desired level is opened, and the transfer mechanism M holding the wafer W is loaded into the processing container 10 through the loading/unloading port lla from a transfer chamber (not shown) disposed adjacent to the processing container 10 and having a vacuum atmosphere. Then, the wafer W is transferred to a position above the support pins 71. During this transfer, the placement base 30 is moved to a position above the support pins 71 and below the wafer W. Further, the moving shield member 82 is supported by the leg member 31, and is moved to a position above the support pins 71 and below the wafer W together with the placement base 30. Therefore, the opening 81a of the fixed shield member 81 is opened.

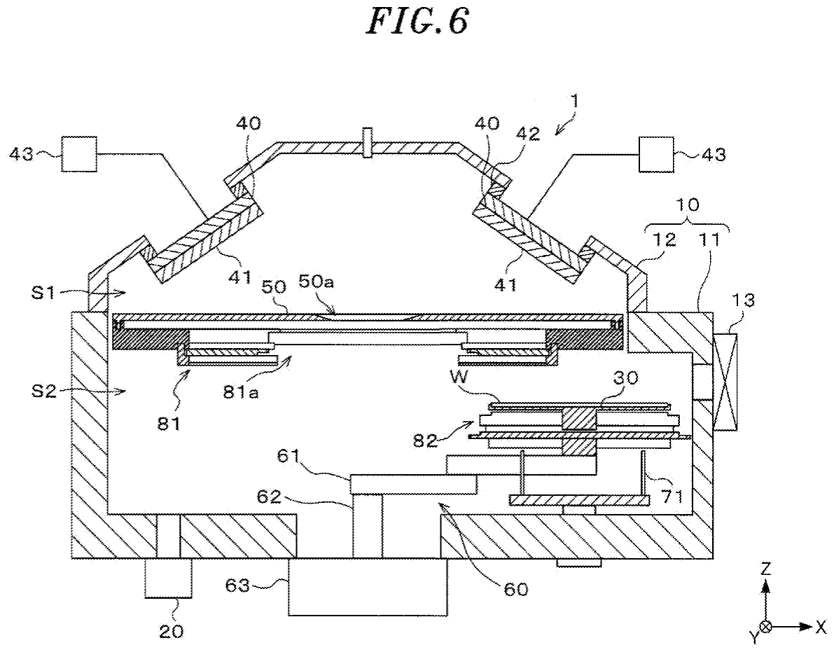

Next, the upward movement of the support pins 71, the unloading of the transfer mechanism M from the processing container 10, the closing of the gate valve 13, and the downward movement of the support pins 71 are sequentially performed. As shown in FIG. 6, the wafer W is delivered from the transfer mechanism M to the placement base 30 via the support pins 71.

In this example, the wafer W is delivered between the placement base 30 and the transfer mechanism using the delivery mechanism 70 having the support pins 71. However, the wafer W may be directly delivered between the placement base 30 and the transfer mechanism without using the delivery mechanism 70. In this case, the moving shield member 82 may not have the through-holes for the support pins 71.

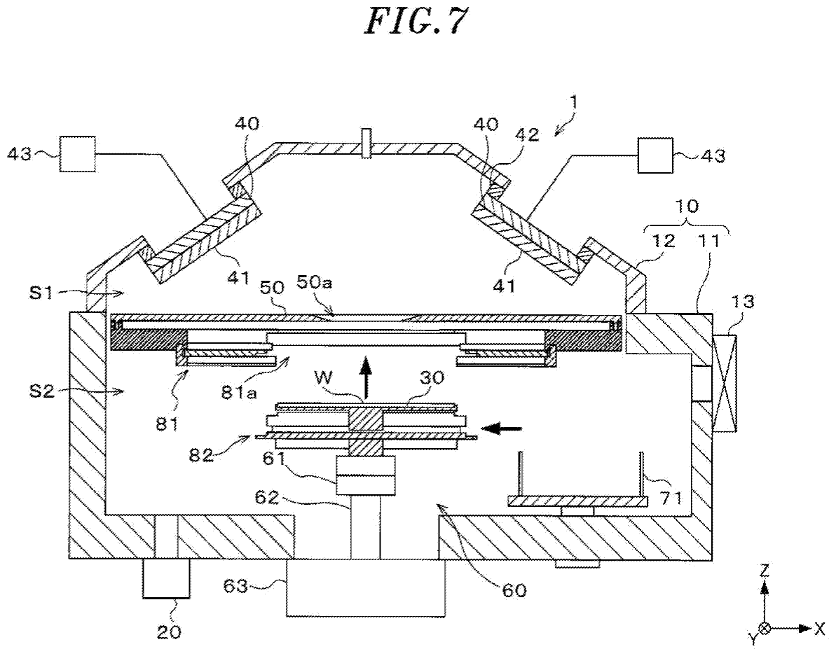

Next, as shown in FIG. 7, the placement base 30 and the moving shield member 82 are moved to the position below the opening 81a of the fixed shield member 81. In other words, the placement base 30 and the moving shield member 82 are moved on the axis of the driving shaft 62 of the movement mechanism 60. In this case, the placement base 30 and the moving shield member 82 are moved linearly along the device depth direction (X-direction in the drawing). Then, the placement base 30 and the moving shield member 82 are moved upward by the movement mechanism 60 until the wafer W is loaded into the movement space S21, specifically, until the placement base 30 is located in the movement space S21. In this case, the position (hereinafter, referred to as “preliminary position”) of the moving shield member 82 is slightly lower than the position (hereinafter, referred to as “defined position”) where the movement space S21 and the path space S23 are defined.

Next, the support pins 91 of the movement mechanism 90 are moved to a position below the moving shield member 82. Then, the support pins 91 are moved upward, and the moving shield member 82 is moved from the preliminary position to the defined position. Specifically, the support pins 91 are moved upward, and as shown in FIG. 4, the upper ends of the support pins 91 and the bottom surface of the moving shield member 8 are brought into contact with each other. Then, the upward movement of the support pins 91 is continued, so that the moving shield member 82 is no longer supported from below by the placement base 30 and is moved upward independently from the placement base 30. The upward movement of the support pins 91 is continued until the opening 81a of the fixed shield member 81 is closed. In other words, as shown in FIG. 3, the upward movement of the support pins 91 is continued until the movement space S21 and the path space S23 are defined by the lower shield member 80 (the fixed shield member 81 and the moving shield member 82) and the upper shield member 50.

The amount of upward movement of the moving shield member 82 by the support pins 91 is set such that both an upper gap Dl (see FIG. 3) between the moving shield member 82 and the leg member 31 and a lower gap D2 (see FIG. 3) between the moving shield member 82 and the leg member 31 are about several mm.

Further, it is preferable that the position where the upper ends of the support pins 91 are in contact with the bottom surface of the moving shield member 82 is distant from the outlet of the path space S23 (i.e., between a bottom wall 821 of a lower body 820 and a bottom wall 831 of a lower body 830 which will be described later).

In this example, the moving shield member 82 is moved to the preliminary position together with the placement base 30 by the movement mechanism 60 and, then, the moving shield member 82 is moved to the defined position by the movement mechanism 90. However, the moving shield member 82 may be moved to the defined position together with the placement base 30. In this case, the placement base 30 moving in the movement space S21 along the device depth direction slides along the upper surface of the moving shield member 82 or the like. Further, in this case, the movement mechanism 90 may be omitted.

When the upward movement of the placement base 30 and the moving shield member 82 is completed, a metal film is formed by sputtering. Specifically, Ar gas, for example, is introduced into the processing container 10 through the gas introducing member 12a, and the exhaust amount is controlled by the exhaust device 20 to adjust a pressure in the processing container 10 to a desired level. Further, a power is supplied from the power supply 43 to the holder 40, and a magnet unit (not shown) is driven. The Ar gas in the processing container 13 is ionized by the power from power supply 43, and electrons generated by the ionization are drifted by a magnetic field generated by the magnet unit (not shown) and an electric field generated by the power from the power supply 43, thereby producing high-density plasma. The surface of the target 41 is sputtered by Ar ions generated in the plasma, and sputtered particles are deposited on the wafer W to form a metal thin film. During the formation of the metal film by sputtering, the placement base 30 moves in the movement space S21 in one direction in the device depth direction (from the positive side toward the negative side in the X-direction in the drawing). However, during the formation of the metal film, the placement base 30 may reciprocate in the device depth direction (X-direction in the drawing).

When the formation of the metal film is completed, the wafer W is unloaded from the movement space S21 and unloaded from the processing container 10. The unloading processes are performed in the reverse order of the loading processes.

In this manner, the film formation performed by the film forming apparatus 1 is completed.

As described above, the film forming apparatus 1 according to the present embodiment includes the processing container 10 configured to be depressurized, the placement base 30 disposed in the processing container 10 and having the placement surface 30a on which the wafer W is placed, and the holder 40 disposed in the processing container 10 and configured to hold the target 41. The film forming apparatus 1 further includes the upper shield member 50 configured to divide the space in the processing container 10 into the upper space S1 where the holder 40 is disposed and the lower space S2 where the placement base 30 is disposed. The upper shield member 50 has the slit 50a penetrating therethrough in the vertical direction. The film forming apparatus 1 further includes the movement mechanism 60 for moving the placement base 30 in the movement direction parallel to the placement surface 30a and for moving the placement base 30 in the vertical direction in the movement space S21 including the space directly below the slit 50a in the lower space S2, the leg member 31 configured to connect the placement base 30 and the movement mechanism 60, and the lower shield member 80 for defining the movement space S21 together with the upper shield member 50. The lower shield member 80 defines the path space S23 that connects the movement space S21 and other space S22 in the lower space S2, and the leg member 31 passes through the path space S23 when the placement base 30 moves in the movement direction. Further, the lower shield member 80 includes the fixed shield member 81 fixed in the lower space S2 and having the opening 81a forming an intake outlet of the placement base 30 with respect to the movement space S21, and the moving shield member 82 configured to be movable in the lower space S2 and the moving shield member 82 configured to be moved downward in the lower space S2 to open the opening 81a and moved upward in the lower space S2 to close the opening 81a to thereby define the movement space S21 and the path space S23. Therefore, in the present embodiment, the moving shield member 82 for opening/closing the opening 81a forming an intake outlet of the placement base 30 with respect to the movement space S21 is moved to retract to the lower space S2, rather than the upper space S1 where the holder 40 of the target 41 is disposed, in order to open the opening 81a. Accordingly, even if two holders 40 are disposed in the upper space S1 as in the present embodiment, the moving shield member 82 does not interfere with any of the holders 40. Further, even if members for adjusting a film formation type are additionally provided in the upper space S1, these members and the moving shield member 82 do not interfere with each other. Hence, in the present embodiment, a larger number of members can be additionally disposed in the upper space S1.

Further, in the present embodiment, the path space S23 has a serpentine shape in the cross-section taken in the movement direction of the placement base 30. Therefore, it is possible to suppress sputtered particles from the target 41 located in the upper space S1 from reaching the other space S22 in the lower space S2 through the movement space S21 and the path space S23. As a result, it is possible to suppress deposition of the sputtered particles in the other space S22 where the movement mechanism 60 and the like are disposed, and also possible to suppress unnecessary film formation on the inner wall of the processing container 10 facing the movement mechanism 60 or the lower space S2. In other words, in the present embodiment, it is possible to prevent the sputtered particles from the target 41 from being unnecessarily deposited in the film forming apparatus 1.

Further, in the present embodiment, the leg member 31 has a shape corresponding to the path space S23 in the cross-section taken in the movement direction of the placement base 30. Thus, when the placement base 30 moves in the movement direction, the lower shield member 80 that defines the path space S23 and the leg member 31 do not interfere with each other.

Further, in the configuration of the film forming apparatus 1 according to the present embodiment, it is possible to cope with the change in the vertical distances (heights) from the targets 41 to the placement base 30 by changing the heights of the upper shield member 50 and the fixed shield member 81. In other words, in the present embodiment, the heights from the targets 41 to the placement base 30 can be easily changed.

Further, in the film forming apparatus 1 according to the present embodiment, it is possible to cope with the change in the movement direction of the placement base 30 with respect to the target 41 simply by changing the directions of the upper shield member 50 and the lower shield member 80. In other words, in the present embodiment, the movement direction of the placement base 30 with respect to the target 41 can be easily changed.

Next, the lower shield member 80 and the leg member 31 will be described. In the following, the term “X-direction in the drawing” may be used instead of the term “device depth direction” used in the above description. Similarly, the term “Y-direction” may be used instead of the term “device width direction”, and the term “Z-direction” may be used instead of the term “vertical direction.”

First, the moving shield member 82 will be described with reference to FIG. 3.

The moving shield member 82 has two upper bodies 800, 810 and the two lower bodies 820 and 830. The moving shield member 82 has an overall circular shape when viewed from top and bottom, for example.

The upper body 800 covers a side surface of a neck portion 300 (to be described later) of the leg member 31 on the positive side in the Y-direction, and an upper outer surface of a curved portion 310 (to be described later) of the leg member 31 on the positive side in the Y-direction.

The upper body 800 has, at an upper end thereof, a ceiling wall 801 having a flat plate shape extending in the X-direction and the Y-direction. The ceiling wall 801 defines the bottom surface of the movement space S21.

A vertical wall 802 extending downward from the bottom surface of the ceiling wall 801 is formed at the end of the ceiling wall 801 on the negative side in the Y-direction. The vertical wall 802 is formed in a rectangular flat plate shape extending in the X-direction and the Z-direction. Further, the vertical wall 802 is formed to have a gap of about several cm between the lower end thereof and the upper surface of the lower body 830.

A vertical wall 803 extending downward from the bottom surface of the ceiling wall 801 is formed at the center of the ceiling wall 801 in the Y-direction. The vertical wall 803 has a rectangular flat plate shape extending in the X-direction and the Z-direction. Further, the vertical wall 803 is formed such that the lower end thereof is located on the substantially same plane as the lower end of the vertical wall 802.

The portion of the ceiling wall 801, which is disposed more outward than the vertical wall 803, is formed in a semicircular shape when viewed from above, and a semicircular wall 804 having a semicircular shape when viewed from above is formed along the peripheral portion thereof. The semicircular wall 804 is formed to extend downward from the bottom surface of the ceiling wall 801. Further, as will be described later, the outer portion of the semicircular wall 804 is curved in the cross-section taken in the circumferential direction about the central axis of the moving shield member 82 such that the gap between the fixed shield member 81 and an upper member 900 to be described later has a serpentine shape in the corresponding cross-section. Specifically, the outer portion of the semicircular wall 804 is formed in a hook shape curved upward in the corresponding cross-section. The upper body 800 is fixed to the lower body 820 in a state where the lower end of the semicircular wall 804 is in contact with the lower body 820.

The upper body 810 covers the surface of the neck portion 300 (to be described later) of the leg member 31 on the negative side in the Y direction, and the upper outer surface of the curved portion 310 (to be described later) of the leg member 31 on the negative side in the Y direction.

The upper body 810 has a ceiling wall 811 formed in a flat plate shape extending in the X-direction and the Y-direction at the upper end thereof. The ceiling wall 811 defines the bottom surface of the movement space S21.

A vertical wall 812 extending downward from the bottom surface of the ceiling wall 811 is formed at the end of the ceiling wall 811 on the positive side in the Y-direction. The vertical wall 812 is formed in a rectangular flat plate shape extending in the X-direction and the Z-direction. Further, the vertical wall 812 is formed to have a gap of about several cm between the lower end thereof and the upper surface of the lower body 830.

A vertical wall 813 extending downward from the bottom surface of the ceiling wall 811 is formed at the center of the ceiling wall 811 in the Y-direction. The vertical wall 813 is formed in a rectangular flat plate shape extending in the X-direction and the Z-direction. Further, the vertical wall 813 is formed such that the lower end thereof is located substantially on the same plane as the lower end of the vertical wall 812.

The portion of the ceiling wall 811, which is disposed more outward than the vertical wall 813, is formed in a semicircular shape when viewed from above, and a semicircular wall 814 having a semicircular shape when viewed from above is formed along the peripheral portion thereof. The semicircular wall 814 is formed to extend downward from the bottom surface of the ceiling wall 811. Further, as will be described later, the outer portion of the semicircular wall 814 is curved in the cross-section taken in the circumferential direction about the central axis of the moving shield member 82 such that the gap between the fixed shield member 81 and the upper member 900 to be described later has a serpentine shape in the same cross-section. Specifically, the outer portion of the semicircular wall 814 has a hook shape curved upward in the same cross-section. The upper body 810 is fixed to the lower body 820 in a state where the lower end of the semicircular wall 814 is in contact with the lower body 830.

The lower body 820 covers the lower outer surface of the curved portion 310 (to be described later) of the leg member 31 on the positive side in the Y direction.

The lower body 820 has the bottom wall 821 formed in a flat plate shape extending in the X-direction and the Y-direction at the lower end thereof.

A vertical wall 822 extending upward from the upper surface of the bottom wall 821 is formed at the end of the bottom wall 821 on the positive side in the Y-direction. The vertical wall 822 is formed in a rectangular flat plate shape extending in the X-direction and the Z-direction.

A horizontal wall 823 extending from the surface of the vertical wall 822 on the positive side in the Y-direction toward the positive side in the Y-direction is formed at the upper end of the vertical wall 822. The horizontal wall 823 is formed in a flat plate shape extending in the X-direction and the Y-direction and has a semicircular shape when viewed from above.

The lower body 830 covers the lower outer surface of the curved portion 310 (to be described later) of the leg member 31 on the negative side in the Y-direction, and is partially inserted into a recess 311 formed by the curved portion 310 (to be described later) of the leg member 31.

The lower body 830 has the bottom wall 831 formed in a flat plate shape extending in the X-direction and the Y-direction at the lower end thereof.

A vertical wall 832 extending upward from the upper surface of the bottom wall 831 is formed at the end of the bottom wall 831 on the negative side in the Y-direction. The vertical wall 832 is formed in a rectangular flat plate shape extending in the X-direction and the Z-direction.

Further, the lower body 830 has a shielding portion 834 inserted into the recess 311 formed by the curved portion (to be described later) of the leg member 31. The shielding portion 834 has a horizontal wall 834a formed in a flat plate shape extending from the surface at the upper end of the vertical wall 832 on the positive side in the Y-direction toward the positive side in the Y-direction.

A vertical wall 834b extending upward is formed between the vertical wall 813 and the vertical wall 812 of the upper body 810 in the Y-direction on the upper surface of the horizontal wall 834a. Further, a vertical wall 834c extending upward is formed between the vertical wall 802 and the vertical wall 803 of the upper body 800 in the Y-direction on the upper surface of the horizontal wall 834a. The vertical wall 834b and the vertical wall 834c are formed in a rectangular flat plate shape extending in the X-direction and the Z-direction. Further, the upper end of the vertical wall 834b is located above the lower ends of the vertical walls 813 and 812 of the upper body 810. Similarly, the upper end of the vertical wall 834c is located above the lower ends of the vertical walls 802 and 803 of the upper body 800.

Further, the end of the horizontal wall 834a on the positive side in the Y-direction is located on the positive side in the Y-direction compared to the end of the bottom wall 821 of the lower body 820 on the negative side in the Y-direction.

In the moving shield member 82, the space between the ceiling wall 801 of the upper body 800 and the ceiling wall 811 of the upper body 810 serves as an inlet of sputtered particles from the movement space S21. Further, in the moving shield member 82, the space between the bottom wall 821 of the lower body 820 and the bottom wall 831 of the lower body 830 serves as an outlet of sputtered particles moving toward the other space S22.

In the moving shield member 82, the space connecting the inlet of the sputtered particles and the outlet of the sputtered particles, i.e., the path space S23, is covered with the members constituting the moving shield member 82. Further, the horizontal wall 834a, the vertical walls 802, 803, 812, 813, 834b, and 834c are provided in the path space S23, so that the path space S23 has a serpentine shape in the cross-section taken in the X-direction. Hence, it is possible to prevent the sputtered particles from passing through the moving shield member 82 and reaching the other space S22.

The portion (e.g., the negative end in the X -direction and the positive end in the X-direction) of the path space S23 that is not covered by the moving shield member 82 is covered by the fixed shield member 81.

Next, the leg member 31 will be described with reference to FIGS. 3 and 4.

The leg member 31 has the neck portion 300, the curved portion 310, and a base portion 320.

The neck portion 300 is formed in a quadrilateral columnar shape, and has an upper end connected to the center of the bottom surface of the placement base 30 and a lower end connected to a center of an upper surface of an upper wall 312 (to be described later) of the curved portion 310. When the placement base 30 moves in the X-direction, the neck portion passes through the space between the vertical wall 802 of the upper body 800 and the vertical wall 812 of the upper body 810.

The curved portion 310 is curved to form the recess 311 that opens on the negative side in the Y-direction.

The curved portion 310 has the upper wall 312. The upper wall 312 is curved along the space formed by the moving shield member 82. Specifically, the upper wall 312 is curved such that the portions thereof corresponding to the vertical wall 834b and the vertical wall 834c protrude upward. Further, a vertical wall 313 extending downward from the bottom surface of the upper wall 312 at the positive end in the Y-direction is formed. The vertical wall 313 is formed in a rectangular flat plate shape extending in the X-direction and the Z-direction.

A lower wall 314 extending from the surface of the lower end of the vertical wall 313 on the negative side in the Y direction toward the negative side in the Y direction is formed. The lower wall 314 has a thick central portion.

The base portion 320 is formed in a columnar shape, and has an upper end connected to the center of the bottom surface of the lower wall 314 and the lower end connected to the multi-joint arm 61.

The leg member 31 supports the moving shield member 82 when at least one of the following states (A) and (B) is satisfied, as shown in FIG. 4, for example.

(A) a state in which the upper surface of the thick central portion of the lower wall 314 of the leg member 31 is in contact with the bottom surface of the shielding portion 834 in the lower body 830 of the moving shield member 82

(B) a state in which the upper surface of the upwardly protruding portion of the upper wall 312 of the leg member is in contact with the bottom surfaces of the ceiling walls 801 and 811 of the upper bodies 800 and 810

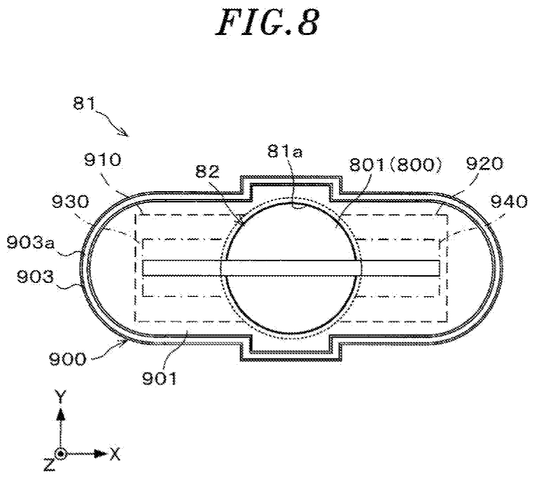

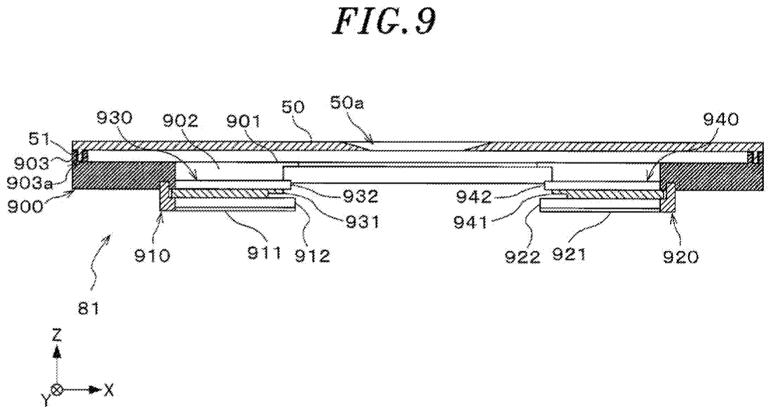

Next, the fixed shield member 81 will be described with reference to FIGS. 8 and 9. FIG. 8 is a top view of the fixed shield member 81, and shows a state in which the opening 81a is closed by the moving shield member 82. FIG. 9 is a partially enlarged view of FIG. 2.

The movement space S21 has a portion that does not overlap the moving shield member 82 in plan view. Even at this portion of the movement space S21, the fixed shield member 81 is configured as follows to have a serpentine shape in the cross section taken along the X direction.

As shown in FIG. 8, the fixed shield member 81 has the upper member 900, lower members 910 and 920, and intermediate members 930 and 940.

The upper member 900 has substantially the same function as those of the upper bodies 800 and 810 of the moving shield member 82. The upper member 900 has a horizontal wall 901 corresponding to the ceiling walls 801 and 811 of the upper bodies 800 and 810 that define the bottom surface of the movement space S21 and cover the path space S23. The horizontal wall 901 is formed to be continuous with the ceiling walls 801 and 811 when the moving shield member 82 is located at the defined position. Further, the upper member 900 has a vertical wall 902 corresponding to the vertical wall 802 of the upper body 800. The vertical wall 902 is formed to be continuous with the vertical wall 802 when the moving shield member 82 is located at the defined position. Although not shown, the upper member 900 also has a vertical wall corresponding to the vertical walls 803, 812, and 813.

The lower member 910 has substantially the same function as those the lower body 820 of the moving shield member 82 and a part of the lower body 830 on the negative side in the X direction. The lower member 910 has a bottom wall 911 corresponding to the bottom walls 821 and 831 of the lower bodies 820 and 830 that cover the path space S23. The bottom wall 911 is formed to be continuous with the bottom walls 821 and 831 when the moving shield member 82 is located at the defined position. Further, the lower member 910 has a vertical wall 912 corresponding to the vertical wall 822 of the lower body 820 that covers the path space S23. The vertical wall 912 is formed to be continuous with the vertical wall 822 when the moving shield member 82 is located at the defined position. Although not shown, the lower member 910 also has a vertical wall corresponding to the vertical wall 832.

The lower member 920 has substantially the same function as those of the lower body 820 of the moving shield member 82 and a part of the lower body 830 on the positive side in the X direction. The lower member 920 has a bottom wall 921 corresponding to the bottom walls 821 and 831 of the lower bodies 820 and 830 that cover the path space S23. The bottom wall 921 is formed to be continuous with the bottom walls 821 and 831 when the moving shield member 82 is located at the defined position. Further, the lower member 910 has a vertical wall 922 corresponding to the vertical wall 822 of the lower body 820 that covers the path space S23. The vertical wall 922 is formed to be continuous with the vertical wall 822 when the moving shield member 82 is located at the defined position. Although not shown, the lower member 920 also has a vertical wall corresponding to the vertical wall 832.

The intermediate member 930 has substantially the same function as that of the shielding portion 834 of the lower body 830 of the moving shield member 82 on the negative side in the X direction. The intermediate member 930 has a horizontal wall 931 corresponding to the horizontal wall 834a of the shielding portion 834. The horizontal wall 931 is formed to be continuous with the horizontal wall 834a when the moving shield member 82 is located at the defined position. Further, the intermediate member 930 has a vertical wall 932 corresponding to the vertical wall 834c. The vertical wall 932 is formed to be continuous with the vertical wall 834c when the moving shield member 82 is located at the defined position. Although not shown, the intermediate member 930 also has a vertical wall corresponding to the vertical wall 834b.

The intermediate member 940 has substantially the same function as that of the shielding portion 834 of the lower body 830 of the moving shield member 82 on the positive side in the X direction. The intermediate member 940 has a horizontal wall 941 corresponding to the horizontal wall 834a of the shielding portion 834. The horizontal wall 941 is formed to be continuous with the horizontal wall 834a when the moving shield member 82 is located at the defined position. Further, the intermediate member 940 has a vertical wall 942 corresponding to the vertical wall 834c. The vertical wall 942 is formed to be continuous with the vertical wall 834c when the moving shield member 82 is located at the defined position. Although not shown, the intermediate member 940 also has a vertical wall corresponding to the vertical wall 834b.

Since the fixed shield member 81 is configured as described above, the path space S23 is defined by the fixed shield member 81 even at the portion of the movement space S21 that does not overlap the moving shield member 82 in plan view, and the path space S23 has a serpentine shape in the cross section taken along the X direction.

In the processing container 10, the lower members 910 and 920, the intermediate members 930 and 940, the upper member 900, and the upper shield member 50 are fixed as follows, for example. In other words, the lower members 910 and 920 are fixed in the processing container 10 while being supported by a support (not shown) disposed in the processing container 10. Further, the intermediate members 930 and 940 are fixed in the processing container 10 while being supported by the lower members 910 and 920, respectively. The upper member 900 is fixed in the processing container 10 while being supported by the lower members 910 and 920. The upper shield member 50 is fixed in the processing container 10 while being supported by the upper member 900.

A sidewall 903 that defines the entire side surface of the movement space S21 is disposed at the peripheral portion of the upper member 900 along the corresponding peripheral portion, and a recess 903a for positioning the upper shield member 50 is formed at the upper portion of the sidewall 903. The upper shield member 50 has a serpentine shape in a cross-section due to the recess 903a and the protrusion 51 formed along the peripheral portion of the upper shield member 50, and the upper shield member 50 is fixed by a support member (shown). Since the gap between the upper member 900 and the upper shield member 50 is formed in a serpentine shape in a cross-section due to the recess 903a and the protrusion 51, it is possible to suppress the sputtered particles from the movement space S21 from reaching the other space S22 through the gap.

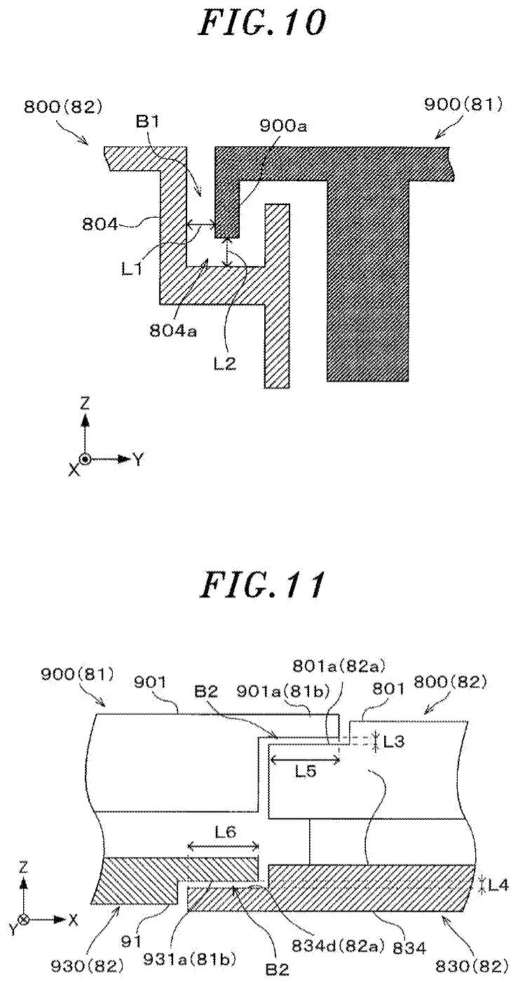

FIG. 10 is a partially enlarged cross-sectional view showing the lower shield member 80 in the area exposed to the upper space S1 through the slit 50a (i.e., area directly below the slit 50a and its vicinity).

As shown in FIG. 10, in the area exposed to the upper space S1 through the slit 50a, a gap B1 between the fixed shield member 81 and the moving shield member 82 has a serpentine shape in the cross-section taken in the circumferential direction about the central axis of the moving shield member 82. Specifically, in the exposed area, the gap B1 between the upper body 800 and the upper member 900 has a serpentine shape in the cross-section taken in the circumferential direction. In order to form the serpentine shape, the semicircular wall 804 of the upper body 800 has a shape curved upward in the cross-section taken in the circumferential direction, and an end of the upper member 900 on the moving shield member 82 side has a shape curved downward in the cross-section taken in the circumferential direction. Further, a tip end 900a of the portion of the upper member 900 that is curved downward in the cross-section taken in the circumferential direction is inserted into a recess 804a formed by the portion of the semicircular wall 804 that is curved upward in the cross-section taken in the circumferential direction. Accordingly, the above-described serpentine shape is formed.

Although not shown, the gap between the upper body 810 and the upper member 900 in the exposed area has the same shape.

When the gap B1 between the fixed shield member 81 and the moving shield member 82 has a serpentine shape in the cross-section taken in the circumferential direction in the area exposed to the upper space S1 through the slit 50a as described above, it is possible to suppress the sputtered particles from the movement space S21 from reaching the other space S22 through the gap B1.

Further, the size of the gap between the fixed shield member 81 and the moving shield member 82 in the area exposed to the upper space S1 through the slit 50a is set to be greater than a thickness of a film to be formed. Specifically, a horizontal size Ll and a vertical size L2 of the gap are set to be greater than a thickness of a film to be formed. Accordingly, it is possible to prevent the gap from being closed by the particles flowing through the slit 50a. Hence, the downward movement of the moving shield member 82 is not hindered by the particles blocking the gap, and it is possible to prevent the contamination of the wafer W from the particles blocking the gap when the moving shield member 82 is moved downward.

FIG. 11 is a partially enlarged cross-sectional view showing the lower shield member 80 in the area that is not exposed to the upper space S1 through the slit 50a.

As shown in FIG. 11, the moving shield member 82 has a stepped surface 82a lower than the central portion at the peripheral portion in the area that is not exposed to the upper space S1 through the slit 50a. Specifically, the moving shield member 82 has stepped surfaces 801a and 834d lower than the central portion at the peripheral portion of the ceiling wall 801 of the upper body 800 and the peripheral portion of the shielding portion 834 of the lower body 830, respectively. On the other hand, the fixed shield member 81 has a cover portion 81b that covers the stepped surface 82a. Specifically, the fixed shield member 81 has a cover portion 901a that covers the stepped surface 801a on the horizontal wall 901 of the upper member 900, and has a cover portion 931a that covers the stepped surface 834d on the horizontal wall 931 of the intermediate member 930.

When the sputtered particles enter the gap B2 between the stepped surface 82a and the cover portion 81b, the sputtered particles enter the gap B2 while alternately colliding with the upper surface of the stepped surface 82a and the bottom surface of the cover portion 81b. The energy of the sputtered particles is reduced by the collision. Therefore, heights L3 and L4 and lengths (length in the radial direction of the moving shield member 82) L5 and L6 of the gap B2 between the stepped surface 82a and the cover portion 81b are set such that the energy of the sputtered particles that have entered the gap B2 becomes zero until the sputtered particles reach the inner end of the gap B2.

In the area that is not exposed to the upper space S1 through the slit 50a, a small amount of sputtered particles reaches the gap B2 between the stepped surface 82a and the cover portion 81b. Even if the sputtered particles reach the gap B2, the heights and lengths of the gap B2 are set as described above, so that it is possible to suppress the sputtered particles from reaching the other space S22 through the gap B2.

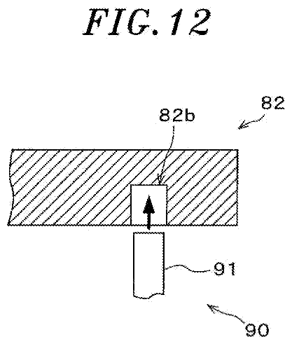

FIG. 12 explains another example of the moving shield member 82.

In the moving shield member 82 of the example of FIG. 12, a recess to be engaged with the upper end of the support pin 91 is formed in the bottom surface in contact with the upper end of the support pin 91 of the movement mechanism 90. With this configuration, it is possible to prevent the moving shield member 82 from being misaligned with respect to the support pin 91 when the moving shield member 82 is moved by the movement mechanism 90 while being supported by the support pin 91.

Similarly, when the moving shield member 82 is supported by the leg member 31 and moved together with the placement base 30 by the movement mechanism 60, the following configurations may be adopted to prevent the moving shield member 82 from being misaligned with respect to the leg member 31. In other words, it is also possible to form a protrusion on one of the contact surface of the leg member 31 with the moving shield member 82 and the contact surface of the moving shield member 82 with the leg member 31, and to form a recess to be engaged with the protrusion on the other contact surface.

It should be understood that the embodiments of the present disclosure are illustrative in all respects and are not restrictive. The above-described embodiments may be omitted, replaced, or changed in various forms without departing from the scope of the appended claims and the gist thereof.

### DESCRIPTION OF REFERENCE NUMERALS

1 film forming apparatus

10 processing container

30 placement base

30a placement surface

31 leg member

40 holder

41 target

50 upper shield member

50a slit

60 movement mechanism

80 lower shield member

81 fixed shield member

81a opening

82 moving shield member

S1 upper space

S2 lower space

S21 movement space

S22 the other space

S23 path space

W wafer

1. A film forming apparatus for forming a film on a moving substrate by sputtering comprising:
a processing container configured to be depressurized;
a placement base disposed in the processing container and having a placement surface on which a substrate is placed;
a holder disposed in the processing container and configured to hold a target;
an upper shield member configured to divide a space in the processing container into an upper space in which the holder is positioned and a lower space in which the placement base is positioned, and has a slit penetrating therethrough in a vertical direction;
a movement mechanism configured to move the placement base in a movement direction parallel to the placement surface and to move the placement base in the vertical direction, in a movement space including a space directly below the slit in the lower space;
a leg member configured to connect the placement base and the movement mechanism; and
a lower shield member configured to define the movement space together with the upper shield member,
wherein the lower shield member further includes:
a fixed shield member fixed in the lower space and having an opening forming an intake outlet of the placement base with respect to the movement space, and configured to define a path space, the path space configured to connect the movement space and other space in the lower space and through which the leg member passes when the placement base moves in the movement direction; and
a moving shield member configured to be movable in the lower space, the moving shield member configured to be moved downward in the lower space to open the opening and moved upward in the lower space to close the opening to thereby define the movement space and the path space,
wherein the path space has a serpentine shape in a cross-section taken along the movement direction, and
the leg member has a shape corresponding to the path space in a cross-section taken along the movement direction.

2. The film forming apparatus of claim 1, wherein the moving shield member is supported by the leg member in a state where the leg member is located in the path space, and is configured to be movable together with the placement base by the movement mechanism.

3. The film forming apparatus of claim 2, further comprising:
an additional movement mechanism configured to move the moving shield member in the vertical direction independently from the placement base.

4. The film forming apparatus of claim 1, wherein a gap between the fixed shield member and the moving shield member has a serpentine shape in a cross-section taken along a circumferential direction at least in an area exposed to the upper space through the slit, and
the gap has a size greater than or equal to a thickness of a film to be formed.

5. The film forming apparatus of claim 2, wherein a gap between the fixed shield member and the moving shield member has a serpentine shape in a cross-section taken along a circumferential direction at least in an area exposed to the upper space through the slit and
the gap has a size greater than or equal to a thickness of a film to be formed.

6. The film forming apparatus of claim 3, wherein a gap between the fixed shield member and the moving shield member has a serpentine shape in a cross-section taken along a circumferential direction at least in an area exposed to the upper space through the slit, and
the gap has a size greater than or equal to a thickness of a film to be formed.

7. The film forming apparatus of claim 1, wherein the moving shield member has a stepped surface lower than a central portion at a peripheral portion in an area that is not exposed to the upper space through the slit,
the fixed shield member has a cover portion that covers the stepped surface, and
a height and a length of a gap between the stepped surface and the cover portion are set such that energy of sputtered particles that have entered the gap from the target becomes zero until the sputtered particles reach an inner end of the gap.

8. The film forming apparatus of claim 2, wherein the moving shield member has a stepped surface lower than a central portion at a peripheral portion in an area that is not exposed to the upper space through the slit,
the fixed shield member has a cover portion that covers the stepped surface, and
a height and a length of a gap between the stepped surface and the cover portion are set such that energy of sputtered particles that have entered the gap from the target becomes zero until the sputtered particles reach an inner end of the gap.

9. The film forming apparatus of claim 3, wherein the moving shield member has a stepped surface lower than a central portion at a peripheral portion in an area that is not exposed to the upper space through the slit,
the fixed shield member has a cover portion that covers the stepped surface, and
a height and a length of a gap between the stepped surface and the cover portion are set such that energy of sputtered particles that have entered the gap from the target becomes zero until the sputtered particles reach an inner end of the gap.

10. The film forming apparatus of claim 4, wherein the moving shield member has a stepped surface lower than a central portion at a peripheral portion in an area that is not exposed to the upper space through the slit,
the fixed shield member has a cover portion that covers the stepped surface, and
a height and a length of a gap between the stepped surface and the cover portion are set such that energy of sputtered particles that have entered the gap from the target becomes zero until the sputtered particles reach an inner end of the gap.
